(19) United States
(12) Patent Application Publication
(10) Pub. No.: US 2005/0242268 A1
(43) Pub. Date: Nov. 3, 2005

(54) Detection apparatus

(76) Inventor: Philip John Oakley, EDINBURGH (GB)

Correspondence Address: Crowell & Moring, P O Box 14300, Washington, DC, 20044-4300, US

(21) Appl. No.: 10/521,750

(22) PCT Filed: Dec. 2, 2004
(86) PCT No.: PCT/GB04/05062

§ 371 Date: Jan. 19, 2005

(30) Foreign Application Priority Data
Dec. 5, 2003 (GB) 0328189.6
Dec. 5, 2003 (EP) 03257673.8

(51) Int. Cl. H01L 27/00

(52) U.S. Cl. 250/208.1

(57) ABSTRACT

A pixelated detector for obtaining images of an object has pixels whose outlines are different. These can be used to achieve improved resolution in use of the detector. To achieve improved resolution, the detector can be moved in relation to the object, so that pixels having smaller dimensions supplement the data obtained with larger pixels. To optimise selection and use of the detector, there may be a priori image information and improved resolution can be obtained without the relative movement.

The present invention relates to detection apparatus. It finds particular application in digital imaging systems.

Known digital imaging systems use pixelated detectors which divide the image of an object into picture elements or “pixels”. Such an imaging system comprises an array of separate sensors, each sensor providing one pixel of the image provided by the array. In use, a pixelated detector can be read out as a series of readings, such as grey scale measurements, from each of the sensors to produce a digital “image signal” representing the readings. The image signal can then be displayed, immediately or after storage and/or further processing, as an image using a display space which is also pixelated.

The pixelation of display spaces is usually based on a rectangular grid. Although the individual pixels are not generally directly mapped to the pixels of the detector producing the image signal, it is easier if the two sets of pixels have a simple relationship and detector designs generally aspire to a rectangular grid of pixels.

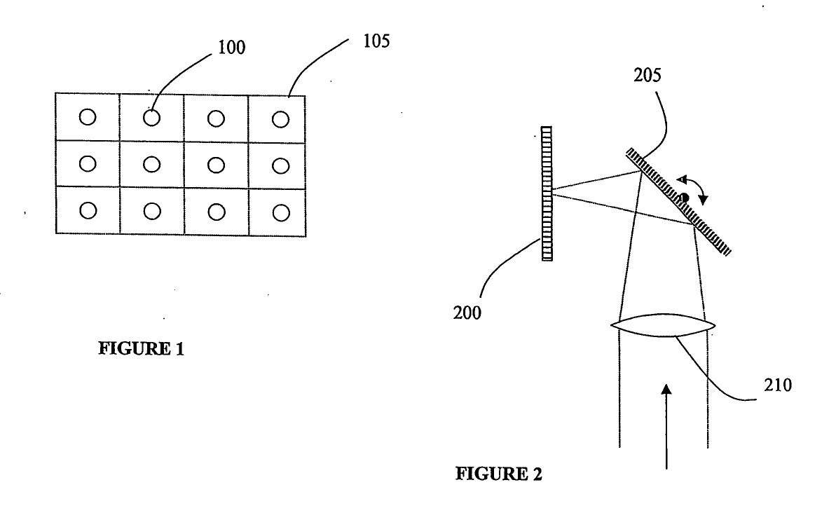

The array of sensors in a detector is usually a regular distribution producing rectangular, or occasionally another arrangement such as hexagonal, pixels. An array of sensors 100 is shown in FIG. 1 which produces rectangular pixels 105.

The outline of the pixels in an array is called a tessellation grid, being a pattern formed by the repetition of a single unit or a shape that, when repeated, fills an area with no gaps and no overlaps. The detected area of a pixel may not completely fill the tessellation grid, though this is desirable for sensitivity.

Various factors can reduce the quality of an image produced by a pixelated detector and techniques have been developed to ameliorate them. For example, a factor which arises in sequential digital imaging systems is “camera shake” between one image and a following image which can cause blur in the image sequence seen by the human viewer. At least two methods for minimising the effects of camera shake have previously been proposed. These are mechanical stabilisation and digital stabilisation and these are further described below:

Mechanical Stabilisation:

Referring to FIG. 2, relatively slow, large scale motion of an object or view relative to a pixelated detector 200 being used to image it can be compensated by external mechanical image steering mechanisms which sense the relative motion and stabilise the image. These external mechanisms, for example a lens 210 and tilting mirror 205, use space, weight and power and are not suitable for correcting for quick or small movements of an object relative to a detector.

Digital Stabilisation:

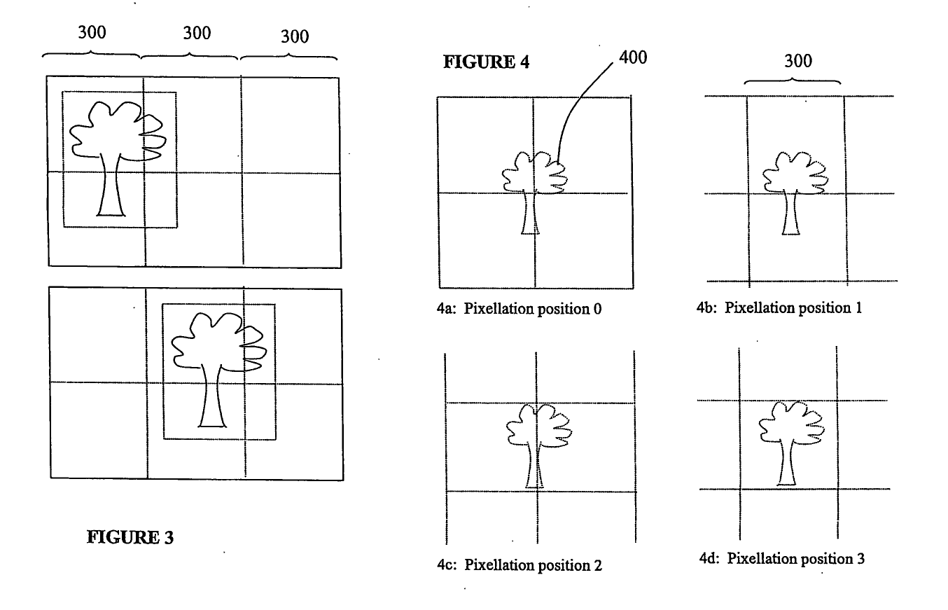

Referring to FIG. 3, large scale motion of an object or view relative to the detector's pixel size has also been removed by sensing the relative motion of the detector with respect to the scene in whole pixel steps 300 and applying whole pixel lateral shifts to images in an image sequence to provide a stable image.

Another factor which can reduce image quality, particularly the resolution of an image produced of an object, is the division of the image into pixels. As a general rule, the smaller the pixels the better the resolution but there is a loss in sensitivity and there can be physical problems in reading out the data from larger numbers of smaller pixels. A known way to improve resolution without reducing the size of the pixels is micro-scanning and this is described below.

Micro-Scan:

Referring to FIG. 4, the resolution limits of the detector can be improved by combining a series of images, each taken with the detector moved by a fraction of the pixel pitch relative to the other images in the series. A favoured integer fraction is a ½pixel step as shown in FIG. 4. In the example the tree 400 is only the size of a pixel 300 and cannot be resolved in a single image. However, with four images in pixellation positions 0 through to 3 as shown, each shifted a ½pixel step up, down or sideways, then depending on its presentation relative to the pixel the tree's brightness may vary from full brightness down to a quarter brightness. Position 3 as shown is the micro-scan position corresponding to full brightness. The inclusion of additional images avoids the ‘hard’ spatial Nyquist limit at the expense of slowing the overall process—the reproduced image requires the complete micro-scan series.

Reference to the Nyquist limit here is to the known effect that after sampling at frequency fₛ, the original frequency content cannot be resolved to better than f_{8/}2, so a 100 Hz sampling frequency cannot resolve frequencies frequency within the 0-50 Hz band which reduces the quality of an image.

In imaging using known detectors, the Nyquist limit often produces a particular problem with features of an object which appear as parallel bars or lines, such as fence posts or railings. Such features have a regular spatial frequency. Depending on the sampling rate of the detector, some of them can be lost in the image, the feature being reproduced at a reduced spatial frequency.

It is known to use more than one array of sensors in generating an image of an object but these are for obtaining partial images in different colours which are then combined to get a full image. However, the pixels within each array are all the same and there is no advantage gained with reference to sampling and the Nyquist limit.

According to a first aspect of the present invention, there is provided a pixelated detector for providing an image signal representing an object, the detector comprising an array of sensing pixels for generating image data from different respective areas of the object, the image data together providing the image signal, wherein the outlines of at least two pixels in the array are different.

Although the pixels may also generate colour related image data, the purpose of embodiments of the present invention is to improve resolution as discussed below and thus the image data of interest in embodiments of the present invention comprises data which is independent of or in addition to colour.

Another difference in relation to the colour sensing arrays mentioned above is that in the array of sensing pixels in embodiments of the present invention, each pixel senses image data from a different respective position on the object at any one time and it is these pixels within a single array which show outlines which are different. In the colour sensing arrays, all the pixels of each colour-related array are generally the same.

The outlines might be different in any one or more of a number of ways. They might be for instance of different sizes and/or shapes. Alternatively or additionally, the outlines might be differently spaced from outlines of neighbouring pixels. If the at least two pixels are each non-circular, they might show relative rotation so that their outlines are tilted relative to one another.

The use of an array in which the outlines of at least two pixels are different opens up the possibility of getting improved resolution without either losing sensitivity or increasing the total number of pixels in the array.

In a first type of arrangement according to an embodiment of the invention, there may be relative movement between the detector and the object (whether natural or deliberate) during the process of providing a digital image signal representing the object. More than one component image signal can then be obtained with the detector, the component image signals being processed together to provide a common output image signal for the object, in a manner akin to micro-scanning. In arrangements of this type, in which there is relative motion, more than one pixel output can be used in taking a reading from the same part of an object. This allows pixels with different characteristics to be used for the same part of the object and thus different benefits can be obtained and the output image signal improved. For example, where two pixels of different sizes are used to view the same part of an object, the larger pixel tends to maintain sensitivity of the detector while the smaller pixel can improve resolution. As long as the distribution of smaller pixels over the array and the direction and speed of the relative movement between array and object are appropriate, this improved resolution can be obtained over the whole object. Overall the number of the pixels is not as great as would be the case if the sizes of all the pixels in the detector array were reduced to that of the smaller pixel and physical readout problems from arrays of larger numbers of small pixels can thus be avoided.

Although this arrangement is akin to micro-scanning, fewer additional readings are necessary to get the same degree of resolution for the same number of pixels in an array.

In this first type of arrangement, perhaps surprisingly, it is possible to get improved resolution even when the outlines of the at least two pixels are the same size and shape, but just differently orientated. This is the case as long as the dimensions of the two outlines are different in the direction of movement. One of the two outlines will have a smaller dimension in the direction of movement and thus provide improved resolution. To achieve this, one of the outlines might be the same except that it is rotated relative to the other.

Where the dimensions of two outlines are different in the direction of movement, this allows problems to be overcome which arise from the regularly spaced sampling provided by regular arrays of identical pixels. As mentioned above, the Nyquist limit can introduce loss of information from some regular patterns in an object, such as where a regular array of rectangular pixels is used to scan a set of parallel lines or bars of a “picket fence” type of object. In a first embodiment of the invention, the pixels of a pair can be rotated with respect to one another so that the dimension of the pixels in the direction of movement is different. Then a lack of resolution which might occur for one pixel of the pair, because its dimension in the direction of movement is relatively large, might not occur for the other, rotated pixel of the pair because its dimension in the direction of movement is less.

A very simple form of the first embodiment of the invention comprises a detector in which the array of pixels has a “herringbone” formation, individual pixels having a rectangular outline but in which alternate rows of pixels are slanted relative to their neighbouring rows. The slanting of one row relative to the next can be at 90°, which means the detected area of the pixels can fill the tessellation grid. If this herringbone formation is then moved relative to an object in a direction parallel to sides of the pixels, then any point on the object will be scanned alternately across the long and the short dimensions of the rectangular pixels. This provides the improved resolution without loss of sensitivity described above.

In a second embodiment of the invention, one or more pixels of a pair in the array has an irregular outline, for instance showing symmetry about only one axis or about no axis. These pixel(s) can also contribute to overcoming the Nyquist limit by contributing a non-regular feature in an otherwise regular pattern in the array. An example of an irregular outline is one in which a pixel has at least a section of its outline jittered out of smooth alignment with a neighbouring section.

An “object” in this context is intended to mean anything from which electromagnetic radiation might be reflected or emitted for detection in providing an image signal and might include for example any of the following: scenes; graphics material; patterns; material distributions; and/or articles.

In a detector where more than one pixel size and/or shape is used, it is possible to produce a detector having more than one tessellation grid.

It is not essential that there is relative movement between a detector and an object of which it is used to form an image. If there is no relative movement, however, it is preferable that at least two pixels of a detector array have different areas. This allows the detector to benefit from the improved resolution of the smaller pixel(s). The presence of the smaller pixel(s) can mean the Nyquist limit inherent in the use of a pixelated detector which is even partly regular is raised (in the frequency domain), in spite of not increasing the total number of pixels.

In an arrangement in which there is no relative movement, a detector can be more effective if there is a priori information available about the object and/or its image. The information can be used in producing and/or processing an image signal to improve its efficiency. In an example of using a priori information, the aim of using a detector might be to find a particular target in a scene. The target may have known spatial characteristics. For example, it may have a feature with parallel edges which are a characteristic distance or distances apart. These edges represent one or more repetition frequencies in the frequency domain and a particular spatial separation in an image of the scene. It is then possible to select a detector to image the scene which has a distribution of differently sized pixels which can be expected to enable resolution of the feature. The data this detector will produce is likely to lead to improved recognition of the target compared with a detector of known type, having a regular array of the same number of pixels but where the pixels are identical.

Where the detector is to be used in detecting features with parallel edges as described above, it may be found preferable that the dimensions of the two outlines in the direction of movement are at least generally based on a parallel-sided outline as this may optimise resolution of the features using the a priori image information.

The distribution of pixels in a detector having a smaller area, or dimension in a given direction, can clearly be important. A feature in a target may still not be resolved if the higher resolution pixels are spread too far apart in the detector. It is therefore best to select a detector for a target having known detectable characteristics where the detector has a sufficient number of higher resolution pixels, closely enough spaced, to pick up the detectable characteristics. Hence if a detectable characteristic has a size n×n average pixel sizes at the detector, then one might choose a distribution of pixel sizes such that at least one pixel in every n² pixels is a higher resolution pixel. This gives a reasonable probability that there will be a higher resolution pixel applied to the detectable characteristic within a relevant time period to allow both image registration and improved resolution.

In embodiments of the present invention, the detector is preferably provided with image signal processing apparatus for use in providing an output signal for use in driving a display. The processing apparatus can be local to the detector or remote from it, for instance receiving image signals over a network. The display is typically also pixelated and known display spaces will provide a regular array of identical pixels. Embodiments of the invention will generally produce an image with improved resolution and the display space will need to be selected to have sufficient resolution to display it. Thus the display space is likely to have a higher number of pixels than the detector.

Another factor in detector design is the manner of physically reading out signals from the individual sensors. Known technology for doing this uses a grid of contact points, one per sensor, which deliver output signals to a read out circuit printed circuit board (PCB). Existing PCBs tend to have a squared or rectangular distribution of points for accepting the signals and there can be an advantage in embodiments of the invention in using a pixelation scheme which allows the grid of contact points to maintain a squared or rectangular distribution.

According to a second aspect of the present invention, there is provided a method of obtaining an image of an object using a pixelated detector, the method comprising the steps of:
i) obtaining a first series of output signals from respective pixels of the detector representing a first image of the object;
ii) obtaining a second series of output signals from respective pixels of the detector; and
iii) processing the first and second series of output signals to produce a single digital representation of the object,

wherein at least one output signal from each of the first and second series overlaps in relation to the object, the overlapping output signals having been produced by pixels having different respective outlines.

It may be preferred in embodiments of the present invention to use a reduced number of readings in producing an image of an object. For example, where at least two sets of readings have been obtained with the detector in different positions in relation to an object, it may be preferred to use only readings from smaller pixels in the second set of readings. These can produce a significant improvement in resolution while the readings from the bigger pixels may add little to the data already collected.

The concept behind embodiments of the present invention is that of a pixelated detector for which the pixel size, shape and/or placement in the detector varies in a manner which can enhance the data gathering quality of the detector. The variation in pixel size, shape and/or placement can produce variation in resolution across an image. Particularly where there is a priori image knowledge and/or when the object is viewed with two or more spatial displacements, added information from the variation in resolution can be utilised. This variation in resolution can increase the ability of the detector firstly to locate a feature in an image and secondly to re-register an image of an object after large scale movement of the detector relative to the object as described under the heading “Mechanical Stabilisation” above. It also supports the known technique of interpolation of the image using predictive filters.

The concept is related to the theoretical work of Shapiro and Silverman (1960 JSIAM V8/2) and Beutler (1966 SIAM rev V8/3, 1974 I&C V26/312). These works identify the mathematical possibility of alias-free sampling of random noise, the error-free recovery of signals from irregularly spaced samples, and the recovery of randomly sampled signals by simple interpolators.

Embodiments of the present invention have the advantage that, apart from the detector design to give a desired pixel distribution, there need be no new components in the imaging system beyond the variation of the readout electronics to support the improved resolution. For the simple case the changes can be truly minimal.

A pixelated detector will now be described as an embodiment of the present invention, by way of example only, with reference to the accompanying figures in which:

FIG. 1 shows an array of individual sensors arranged to produce rectangular pixels in a pixelated detector according to the prior art;

FIG. 2 shows a mechanical image steering mechanism according to the prior art, for use in compensating relatively slow, large scale motion of an object or view relative to a pixelated detector;

FIG. 3 shows a prior art technique using whole pixel lateral shifts in compensating for camera shake;

FIG. 4 shows four images in different pixelation positions which might be used in the prior art technique of micro-scanning to improve image resolution;

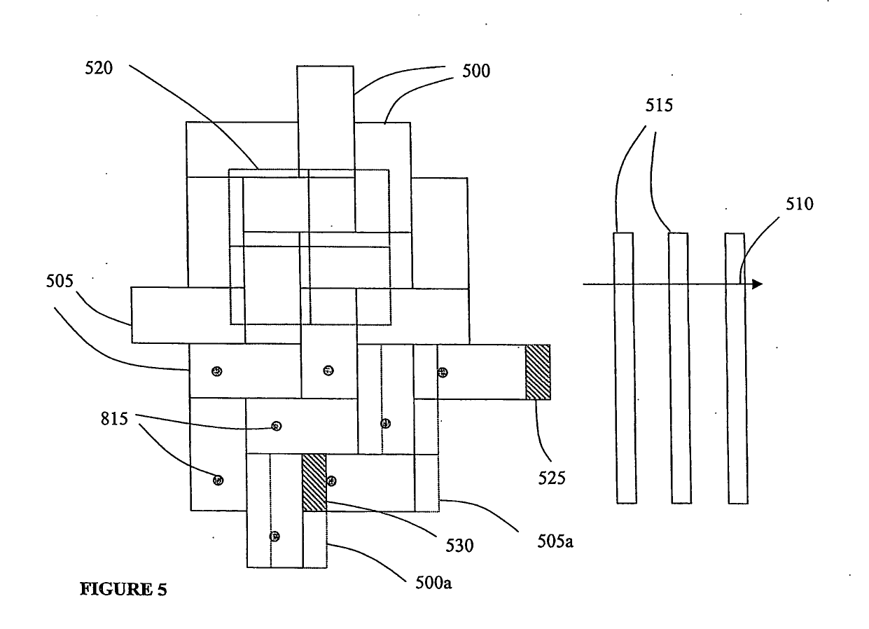

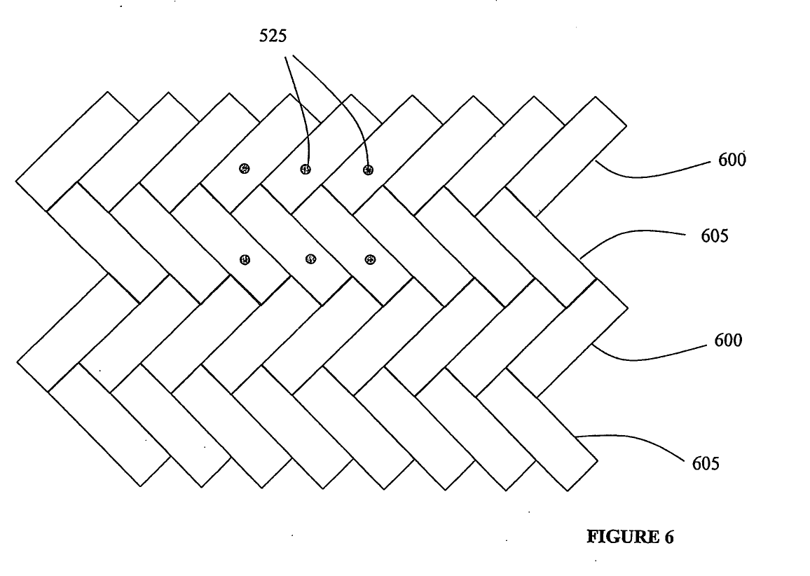

FIG. 5 shows a simple herringbone array of individual sensors for use in a pixelated detector according to the present invention;

FIG. 6 shows an alternative herringbone array to that of FIG. 5;

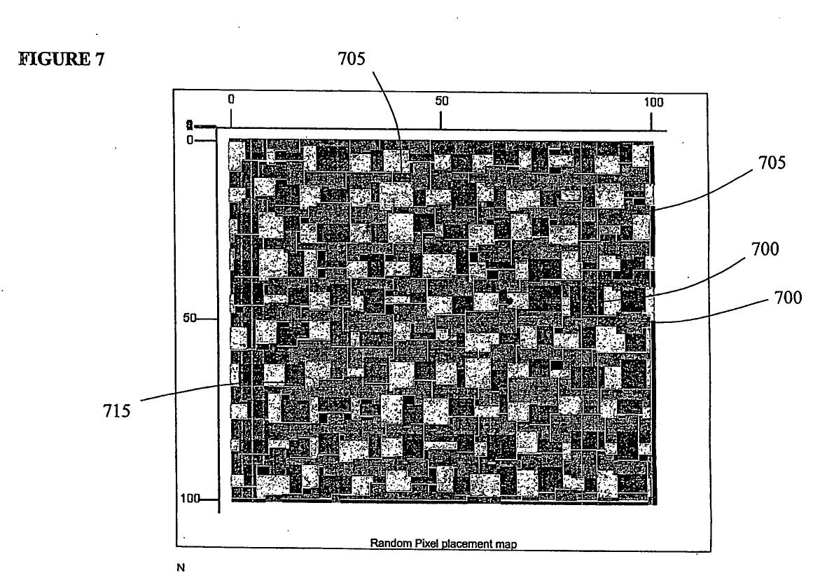

FIG. 7 shows a randomly varied array of individual sensors for use in a pixelated detector according to the present invention; and

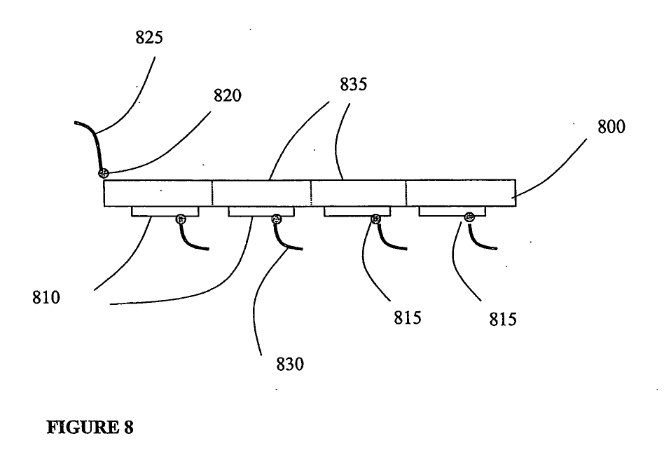

FIG. 8 shows a schematic cross section through a pixelated detector to illustrate how pixels are defined and signals read out from the sensors.

Referring to FIG. 8, pixelated detectors are known, together with fabrication techniques for making them. A suitable form for use in embodiments of the present invention comprises a substrate of semiconductor material 800, for instance comprising materials selected from the III-V groups of the Periodic Table such as gallium arsenide, which has an electrical connection 820, 825 to one side and a set of metallised contact areas 810, using for instance gold, defined lithographically on the other side. Electromagnetic radiation falling on the semiconductor material 800 produces electrical activity in the semiconductor material 800 which can be sensed at the set of contact areas 810, using contact points 815. The distribution of electrical activity in the semiconductor material 800 is mapped to the intensity distribution of the electromagnetic radiation falling on it and the contact areas 810 define pixels 835 across the detector for each of which the electrical activity will be aggregated and taken as a single measurement via respective contact points 815, 830.

The semiconductor material in this context acts both as a common second contact for all the contact areas 810 and as an insulator therebetween.

The shape of each individual pixel is determined by the shape of its respective contact area 810 and can thus be controlled via the lithographic process. In use, electrons produced in the semiconductor material 800 are generally collected by the contact area 810 nearest the point of generation. There are gaps between the contact areas 810 and the collection of the electrons generally produces good delineation between pixels 835 though these gaps are usually minimised in order to maintain sensitivity.

Electrical activity delivered via the contact points 815, 830 is fed to a printed circuit board (not shown) and stored, delivered to a communications network and/or processed appropriately.

Referring to FIGS. 5 and 8, in a first embodiment of a pixelated detector for use in the invention, the individual contact areas 810 of a detector are designed to produce a herringbone array of pixels 500, 505. In this array, only two forms of pixel are used and all the pixels are the same size and based on a rectangle having sides in the ratio 2:1. There are regular rows of tilted pixels. In alternate rows, the pixels 500, 505 have been tilted through 45° in each direction, thus reaching orthogonal positions between pixels in even rows and pixels in odd rows. This alternating variation is repeated across the array.

Four pixels 520 of a prior art detector having the same number of pixels overall are shown in dotted outline, superimposed on the herringbone array 500, 505. These square pixels have a side length which is √2 (that is, 1.41) times the short side length of the pixels of the herringbone array 500, 505.

In use, a herringbone pattern of pixels having the 2:1 aspect ratio can show a resolution improved by up to 141%. Aliasing, previously associated most obviously with bar targets, can be reduced by up to 141%. What previously would have appeared as a moire fringe pattern could be resolved using the herringbone pattern. This was found to be especially true when coupled with micro scanning as mentioned above. The improvement is shown most clearly where an object incorporates a barred feature 515 such as that shown in FIG. 5. As long as the herringbone array is moved so that the short sides of some of the pixels 500 travel orthogonally across the barred feature 515, as indicated by the direction 510 in FIG. 5, then a maximum improvement in resolution of the barred feature can be achieved, compared with the prior art array 520.

In the controlled scenario described above, with movement in a single direction which is known to be orthogonal to the barred feature 515, the herringbone array could be replaced by an array of identical, not tilted, rectangular pixels without losing the improvement in resolution. However, the situation in practice is almost always far less predictable. For instance, neither the general position nor the orientation of a barred feature in an object will necessarily be predictable. By using a herringbone array of pixels, it is only necessary to make one movement of the detector relative to the object, in a direction 510 parallel to the sides of the pixels as shown. If this is done, the probability is very high that a short edge of a pixel will travel sufficiently across the barred feature to give at least some improvement in resolution of the feature in comparison with the prior art. This is further discussed below in relation to an image signal processor.

It will be understood that a barred feature does not necessarily comprise a series of bars or striations as shown but might simply be produced for instance by edges, indentations, or regular variations in brightness of a component within the object.

A set of contact points 815 is shown for some of the pixels 500, 505 in FIG. 5. These would be used as described above in relation to FIG. 8 to read out measurements produced by the pixels to a PCB. As shown, a herringbone array has the advantage that the contact points can be kept in a rectangular formation and thus can be used with existing PCBs, or with PCBs subject to only simple modification.

The degree of improved resolution achieved by using a detector which moves in relation to an object is affected by the distance moved. There is a trade off since the further the detector moves, the more small pixels will “see” a feature which was missed by the bigger pixels but there may also be more of the small pixels which “miss” features altogether. Although the solution might be affected by circumstance, in one arrangement the detector might for instance be moved between consecutive readings over a distance in each direction which is (the ratio of the smallest to the largest pixel dimension in that direction)×(average pixel dimension in that direction).

If a detector as described above were used in a conventional micro-scanning arrangement, there would be over-sampling. It is only necessary to scan the detector as described in one direction, producing two sets of sampling points rather than the four which micro-scanning relies on.

Referring to FIG. 6, in a second example of a herringbone pixel array the pixels 600, 605 are again the same area as each other but based on a rectangle having sides of lengths in the ratio 3:1.

In FIGS. 5 and 6, it can be seen there need be only a minimum gap between the pixels, needed to establish separation of electrons as mentioned above. This maximises sensitivity of the pixelated detector. However, it is not essential that there are only minimum gaps and thus the ratio of the lengths of the sides of the pixels could alternatively be non-integral.

In another variation, the spacing of the pixels in one or more directions across the detector could be non-regular.

Referring to FIG. 7, a more complex embodiment of the invention uses pixels which are primarily arranged in a regular formation but in which the edges are jittered about their nominal position by a significant amount resulting in a two dimensional random sampling action. In one implementation the jitter might be limited to within a +/−half pixel to ensure that the underlying readout process could retain its regular pixelated structure. In others it could be necessary to modify the readout process to reflect what is effectively some repositioning amongst pixels. Part of the jitter extent may then be affected by the interconnection limitation (the physical ability of the manufacturing process to obtain readings from all the pixels). In all cases the jitter should be kept within a limit that will not cause an out of sequence condition to occur in the readout process.

Jitter is a known term, used here to indicate there is random irregularity in the outline of the pixels. There are known ways of generating jitter, such as the linear congruence method in which xₙ₊₁=(axₙ+c) |M|, giving a non-repeating recurrence relation. Further details are available for example at http://mathworld.wolfram.com/LinearCongruenceMethod.html. It is not necessary that there should be entirely random jitter over the whole array of pixels. Realistically, one would use a non-repeating jitter pattern over a set of pixels but then repeat the set of pixesl in the array.

As shown in FIG. 7, the jitter can produce pixels which range in size from relatively large pixels 700 to relatively small pixels 705. There are also black portions 710 indicating “holes” where the pixels do not meet. Otherwise, the pixels generally butt on adjacent edges. Some pixels have a corner 715 cut out where another pixel overlaps. This choice for resolving an overlap is non-critical and other choices are possible. This is further discussed below.

The positional jitter of the pixel edges can have well defined properties allowing both unique and mass produced implementations. A suitable form would be a mathematical pseudo random jitter sequence.

The 2D positional jitter may result in some conflict, for example at the corners of one or more pixels. In some cases overlap occurs whilst in others “holes” occur. The overlap can be resolved in a number of ways: it can be allocated to one, or the other, competing pixel or it can be divided between the two, with a diagonal split being the simplest allocation. In the case of a hole, a possible solution is simply for a hole to remain but it is possible to allocate the unallocated area of the hole to all the adjacent pixels in some suitable ratio. For example, options include allocation of the hole to a single pixel and splitting it in even parts along diagonals to the adjacent pixels.

The variation in pixel sizes means that the data in an image signal may be distorted, particularly where the display space for the image has a regular pixel array. One way to deal with this is to use known non-uniformity correction circuitry (NUC). The NUC computational range can be expanded to cover the distortion in signal caused by variation in pixel size over and above that already present in the overall detector/optical system. The pixel size variation appears merely as larger variations rather than a new problem.

Although the outlines of the pixels shown in FIG. 7 are jittered, it can be seen that they are generally based on a parallel-sided, indeed rectangular, outline. This can be an advantage in resolving features of an object which have parallel striations of some sort since there can be good cutoff between one pixel and its neighbour in an image scan.

An image signal processor for use with embodiments of the present invention would generally be of known type, for instance as used in micro-scanning to process multiple sets of image data obtained with a shift in pixel position on the object. However, less data would be necessary to get improved resolution of features on the object. For example, using a herringbone array of pixels, as shown in FIG. 5, the image data could be taken before and after a shift in a direction 510 parallel to sides of the pixels. This produces the improved resolution in both directions over the object because of the slanting nature of the array. Some pixels 500a, 505a are shown shifted (in dotted outline) in FIG. 5. It can be seen that although the shift is in only one direction 510, there are parts 525 (shown shaded) of an object previously viewed by a vertical pixel, viewed after the shift by a horizontal pixel and parts 530 (again shown shaded) of an object previously viewed by a vertical pixel, viewed after the shift by a horizontal pixel.

The processor might also have other known abilities, such as the ability to interpolate data.

It might only be necessary to collect and/or use data from selected pixels in a second or subsequent pixel position with respect to an object. This might be done for instance where one or more larger pixels produces a high image reading in a first position, indicating a bright spot. It might then be decided only to look at the readings from smaller pixels in a second or subsequent pixel position which coincide with the original position of the one or more larger pixels which indicated a bright spot.

1. A pixelated detector for providing an image signal representing an object, the detector comprising an array of sensing pixels for generating image data from different respective areas of the object, the image data together providing the image signal, wherein the outlines of at least two pixels in the array are different.

2. A pixelated detector according to claim 1 wherein the outlines of at least two of the pixels enclose different areas.

3. A pixelated detector according to claim 1, wherein the outlines of at least two of the pixels are non-circular and show rotation with respect to one another in the detector.

4. A pixelated detector according to claim 1, wherein the outlines of at least two of the pixels have different shapes.

5. A pixelated detector according to claim 1, wherein at least one of the pixels has an irregular outline.

6. A pixelated detector according to claim 5 wherein the irregular outline is jittered.

7. A pixelated detector according to claim 1, wherein the outline of at least one of the pixels shows no symmetry.

8. A pixelated detector according to claim 1, wherein the pixels of the detector do not fill a tessellation grid.

9. A pixelated detector according to claim 8 wherein the outlines of at least three pixels of the detector are irregularly spaced from one another.

10. A pixelated detector according to claim 1, further comprising motion control apparatus for producing controlled motion of the detector relative to an object in use.

11. A pixelated detector according to claim 1, wherein the array of sensing pixels comprises a distribution of pixels over the array which, in at least one direction across the array, have outlines with different dimensions in said at least one direction.

12. A pixelated detector according to claim 1, wherein the array of sensing pixels comprises a distribution of pixels over the array which, in at least two different directions across the array, have outlines with different dimensions in each of said at least two directions.

13. A pixelated detector according to claim 1, wherein the outlines of at least some of the pixels in the array are generally based on a parallel-sided outline.

14. A pixelated detector according to claim 1, wherein said array of pixels comprises a herringbone pattern of rectangular pixels, provided by two sub-arrays of pixels, the long dimensions of the pixels of one sub-array being parallel to one another and slanted with respect to the long dimensions of the pixels of the other sub-array.

15. A pixelated detector according to claim 1, wherein the array of pixels has more than one associated tessellation grid.

16. A pixelated detector according to claim 1, wherein the image data are independent of, or in addition to, colour.

17. A pixelated detector according to claim 1, wherein the detector is provided with a signal processor for processing image signals generated by the detector, wherein the processor is adapted to process a first image signal generated by the detector and a second image signal generated by the detector to generate a third image signal having improved resolution.

18. A method of obtaining an image of an object using a pixelated detector, the method comprising the steps of:
i) obtaining a first series of output signals from respective pixels of the detector representing a first image of the object;
ii) obtaining a second series of output signals from respective pixels of the detector; and
iii) processing the first and second series of output signals to produce a digital representation of the object,
wherein at least one output signal from each of the first and second series, relating to the same position on the object, is obtained from a different respective pixel, said different respective pixels having different outlines with respect to one another.
